(19) United States
(12) Patent Application Publication
(10) Pub. No.: US 2024/0373681 A1
(43) Pub. Date: Nov. 7, 2024

(54) MANUFACTURING METHOD FOR DISPLAY DEVICE AND DISPLAY DEVICE

(71) Applicant: Japan Display Inc., Tokyo (JP)

(72) Inventor: Hiroshi TABATAKE, Tokyo (JP)

(73) Assignee: Japan Display Inc., Tokyo (JP)

(21) Appl. No.: 18/648,631

(22) Filed: Apr. 29, 2024

(30) Foreign Application Priority Data
May 1, 2023 (JP) 2023-075594

(51) Int. Cl. H10K 59/122; H10K 59/12

(52) U.S. Cl. CPC H10K 59/122; H10K 59/1201

(57) ABSTRACT

According to one embodiment, a manufacturing method for a display device includes forming a plurality of lower electrodes, a rib, a partition, a first stacked film including a first organic layer and a first upper electrode, and a first sealing layer. The manufacturing method includes forming a resist individually for each of a plurality of first sub-pixels aligned in a second direction. The manufacturing method includes removing the first sealing layer and the first stacked film using the resists as a mask.

### CROSS-REFERENCE TO RELATED APPLICATION

This application is based upon and claims the benefit of priority from Japanese Patent Application No. 2023-075594, filed May 1, 2023, the entire contents of which are incorporated herein by reference.

### FIELD

Embodiments described herein relate generally to a manufacturing method for a display device and a display device.

### BACKGROUND

In recent years, display devices in which organic light-emitting diodes (OLEDs) are applied as display elements have been put to practical use. This display element comprises a lower electrode, an organic layer covering the lower electrode, and an upper electrode covering the organic layer.

In manufacturing such display devices as described above, there is a need for a technology to suppress the degradation of reliability.

### BRIEF DESCRIPTION OF THE DRAWINGS

FIG. 1 shows a configuration example of a display device according to one embodiment.

FIG. 2 shows an example of a sub-pixel layout.

FIG. 3 is a schematic cross-sectional view of the display device along line III-III in FIG. 2.

FIG. 4 is a plan view illustrating a manufacturing method according to the embodiment.

FIG. 5 is a cross-sectional view illustrating the manufacturing method according to the embodiment.

FIG. 6 is a cross-sectional view illustrating the manufacturing method according to the embodiment.

FIG. 7 is a plan view illustrating a manufacturing method according to a comparative example.

FIG. 8 is a schematic cross-sectional view of a display device along line VIII-VII in FIG. 7.

### DETAILED DESCRIPTION

In general, according to one embodiment, a manufacturing method for a display device includes a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction. The manufacturing method includes forming a plurality of lower electrodes, including a first lower electrode configuring the first sub-pixel, in the display area. The manufacturing method includes forming a rib having a plurality of pixel apertures including a first pixel aperture overlapping the first lower electrode. The manufacturing method includes forming a partition, including a lower part arranged on the rib and an upper part having an end portion protruding from a side surface of the lower part, in the display area. The manufacturing method includes forming a first stacked film including a first organic layer in contact with the plurality of lower electrodes through the plurality of pixel apertures and a first upper electrode covering the first organic layer. The manufacturing method includes forming a first sealing layer covering the first stacked film. The manufacturing method includes forming a resist individually for each of a plurality of first sub-pixels aligned in the second direction. The manufacturing method includes removing the first sealing layer and the first stacked film using the resists as a mask.

According to another embodiment, a display device includes a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction. The display device includes a lower electrode, a rib, a partition, a stacked film and a sealing layer. The lower electrode is arranged in the display area. The rib has a pixel aperture overlapping the lower electrode. The partition includes a lower part arranged on the rib and an upper part having an end portion protruding from a side surface of the lower part. The stacked film includes an organic layer in contact with the lower electrode through the pixel aperture and an upper electrode covering the organic layer. The sealing layer covers the stacked film. A part of the sealing layer overlaps in plan view with the upper part included in the partition. A gap is formed between a part of the sealing layer and an upper surface of the upper part included in the partition.

According to another embodiment, a display device includes a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction. The display device includes a lower electrode, a rib, a partition, a stacked film and a sealing layer. The lower electrode configures the first sub-pixel. The rib has a pixel aperture overlapping the lower electrode. The partition includes a lower part arranged on the rib and an upper part having an end portion protruding from a side surface of the lower part. The sealing layer and the stacked film are patterned using a resist formed individually for each of a plurality of first sub-pixels aligned in the second direction as a mask. The stacked film includes an organic layer in contact with the lower electrode through the pixel aperture and an upper electrode covering the organic layer.

Embodiments will be described with reference to the accompanying drawings.

Note that the disclosure is merely an example, and proper changes in keeping with the spirit of the invention, which are easily conceivable by a person of ordinary skill in the art, come within the scope of the invention as a matter of course. In addition, in some cases, in order to make the description clearer, the drawings show schematic illustration rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as a first direction. A direction parallel to the Y-axis is referred to as a second direction. A direction parallel to the Z-axis is referred to as a third direction. Note that the third direction Z is normal to a plane containing the first direction A and the second direction Y. Further, viewing various elements in parallel with the third direction Z is referred to as planar view.

The display devices of the embodiments are each an organic electroluminescent display device comprising an organic light emitting diode (OLED) as a display element, and is mounted on various types of electronic devices such as televisions, personal computers, in-vehicle devices, tablet terminals, smartphones, mobile phones, wearable terminals and the like.

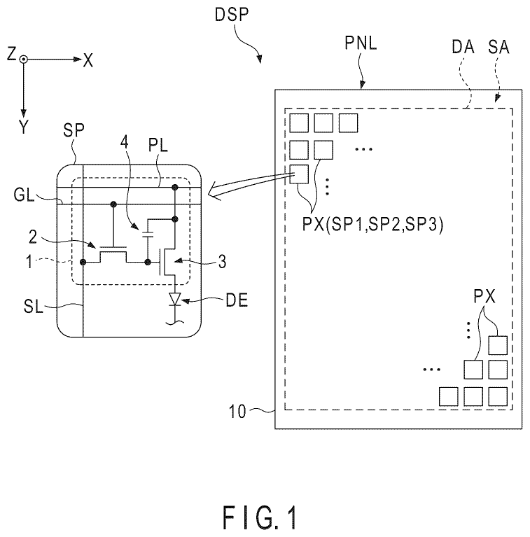

FIG. 1 shows a configuration example of a display device DSP according to the present embodiment. The display device DSP comprises a display panel PNL including an insulating substrate 10. The display panel PNL has a display area DA for displaying images and a peripheral area SA around the display area DA. The substrate 10 may be glass or a flexible resin film.

In the present embodiment, the shape of the substrate 10 in plan view is rectangular. However, the shape of the substrate 10 in plan view is not limited to a rectangle, and may be other shapes such as a square, circle, or oval.

The display area DA comprises a plurality of pixels PX arranged in a matrix in a first direction X and a second direction Y. The pixel PX includes a plurality of sub-pixels SP. In one example, the pixel PX includes a blue sub-pixel SP1, a green sub-pixel SP2, and a red sub-pixel SP3. Note that the pixel PX may include a sub-pixel SP of another color, such as white, together with or instead of any of the sub-pixels SP1, SP2, and SP3.

The sub-pixel SP comprises a pixel circuit 1 and a display element DE driven by the pixel circuit 1. The pixel circuit 1 comprises a pixel switch 2, a drive transistor 3, and a capacitor 4. The pixel switch 2 and the drive transistor 3 are switching elements configured by, for example, thin-film transistors.

A gate electrode of the pixel switch 2 is connected to a scanning line GL. One of source and drain electrodes of the pixel switch 2 is connected to a signal line SL, and the other is connected to a gate electrode of the drive transistor 3 and the capacitor 4. In the drive transistor 3, one of source and drain electrodes is connected to a power line PL and the capacitor 4, and the other is connected to the display element DE.

Note that the configuration of the pixel circuit 1 is not limited to the illustrated example. For example, the pixel circuit 1 may comprise more thin-film transistors and capacitors.

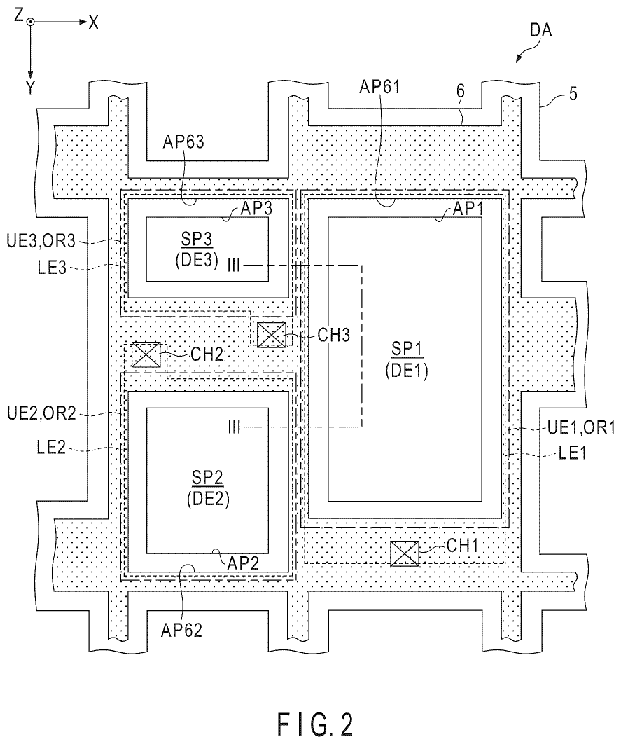

FIG. 2 is a schematic plan view showing an example layout of the sub-pixels SP1, SP2, and SP3. In the example of FIG. 2, the sub-pixels SP2 and SP3 are aligned with the sub-pixel SP1 in the first direction X, respectively. Furthermore, the sub-pixel SP2 and the sub-pixel SP3 are aligned in the second direction Y.

In a case where the sub-pixels SP1, SP2, and SP3 have such a layout, a row in which the sub-pixels SP2 and SP3 are arranged alternately in the second direction Y and a row in which a plurality of sub-pixels SP1 are arranged repeatedly in the second direction Y are formed in the display area DA. These rows are arranged alternately in the first direction X. Note that the layout of the sub-pixels SP1, SP2, and SP3 is not limited to the example in FIG. 2.

A rib 5 is arranged in the display area DA. The rib 5 has pixel apertures AP1, AP2, and AP3 in the sub-pixels SP1, SP2, and SP3, respectively. In the example of FIG. 2, the pixel aperture AP1 is larger than the pixel aperture AP2, and the pixel aperture AP2 is larger than the pixel aperture AP3.

The sub-pixel SP1 comprises a lower electrode LE1, an upper electrode UE1, and an organic layer OR1 that overlap with the pixel aperture AP1, respectively. The sub-pixel SP2 comprises a lower electrode LE2, an upper electrode UE2, and an organic layer OR2 that overlap with the pixel aperture AP2, respectively. The sub-pixel SP3 comprises a lower electrode LE3, an upper electrode UE3, and an organic layer OR3 that overlap with the pixel aperture AP3, respectively.

A portion of the lower electrode LE1, the upper electrode UE1, and the organic layer OR1 that overlaps with the pixel aperture AP1 configures a display element DE1 of the sub-pixel SP1. A portion of the lower electrode LE2, the upper electrode UE2, and the organic layer OR2 that overlaps with the pixel aperture AP2 configures a display element DE2 of the sub-pixel SP2. A portion of the lower electrode LE3, the upper electrode UE3, and the organic layer OR3 that overlaps with the pixel aperture AP3 configures a display element DE3 of the sub-pixel SP3. The display elements DE1, DE2, and DE3 may further include a cap layer as described later. The rib 5 surrounds each of these display elements DE1, DE2, and DE3.

The lower electrode LE1 is connected to the pixel circuit 1 of the sub-pixel SP1 (see FIG. 1) through a contact hole CH1. The lower electrode LE2 is connected to the pixel circuit 1 of the sub-pixel SP2 through a contact hole CH2. The lower electrode LE3 is connected to the pixel circuit 1 of the sub-pixel SP3 through a contact hole CH3.

Above the rib 5 is arranged a partition 6. The partition 6 overlaps with the rib 5 overall and has the same planar shape as the rib 5. That is, the partition 6 has apertures AP61, AP62, and AP63 in the sub-pixels SP1, SP2, and SP3, respectively. In other terms, the rib 5 and the partition 6 are arranged between the display elements DE1, DE2, and DE3 and are lattice-shaped in plan view.

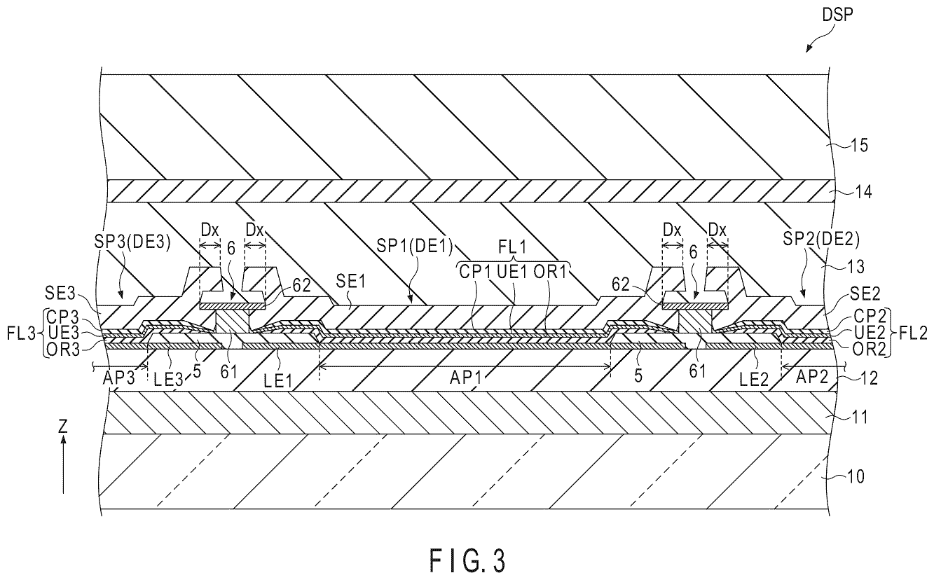

FIG. 3 is a schematic cross-sectional view of the display panel PNL along line III-III in FIG. 2. A circuit layer 11 is arranged on the substrate 10 described above. The circuit layer 11 includes various circuits and wiring, such as the pixel circuit 1, the scanning line GL, the signal line SL, and the power line PL shown in FIG. 1.

The circuit layer 11 is covered by an organic insulating layer 12. The organic insulating layer 12 functions as a planarization film to flatten an unevenness caused by the circuit layer 11. Although not shown in the cross section of FIG. 3, the contact holes CH1, CH2, and CH3 described above are provided in the organic insulating layer 12.

The lower electrodes LE1, LE2, and LE3 are arranged on the organic insulating layer 12. The rib 5 is arranged on the organic insulating layer 12 and the lower electrodes LE1, LE2, and LE3. End portions of the lower electrodes LE1, LE2, and LE3 are covered by the rib 5.

The partition 6 includes a conductive lower part 61 arranged on the rib 5 and an upper part 62 arranged on the lower part 61. The upper part 62 has a greater width than the lower part 61. This causes both end portions of the upper part 62 to protrude beyond the side surfaces of the lower part 61. Such a shape of the partition 6 is referred to as overhanging.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2, and UE3 are in contact with the side surfaces of the lower part 61 of the partition 6.

In the example of FIG. 3, a cap layer CP1 is arranged on the upper electrode UE1, a cap layer CP2 is arranged on the upper electrode UE2, and a cap layer CP3 is arranged on the upper electrode UE3. The cap layers CP1, CP2, and CP3 serve as optical adjustment layers that improve the efficiency of extracting light emitted by the organic layers OR1, OR2, and OR3, respectively.

In the following description, a multilayer including the organic layer OR1, the upper electrode UE1, and the cap layer CP1 is referred to as a stacked film FL1, a multilayer including the organic layer OR2, the upper electrode UE2, and the cap layer CP2 is referred to as a stacked film FL2, and a multilayer including the organic layer OR3, the upper electrode UE3, and the cap layer CP3 is referred to as a stacked film FL3.

Sealing layers SE1, SE2, and SE3 are arranged in the sub-pixels SP1, SP2, and SP3, respectively. The sealing layer SE1 continuously covers the stacked film FL1 and the side surface of the partition 6 around the sub-pixel SP1. The sealing layer SE2 continuously covers the stacked film FL2 and the side surface of the partition 6 around the sub-pixel SP2. The sealing layer SE3 continuously covers the stacked film FL3 and the side surface of the partition 6 around and the sub-pixel SP3.

The sealing layers SE1, SE2, and SE3 are also located on the upper part 62 of the partition 6 surrounding the sub-pixels SP1, SP2, and SP3. In other words, a part of the sealing layers SE1, SE2, and SE3 overlaps in plan view with the upper part 62 of the partition 6. A part of such sealing layers SE1, SE2, and SE3 is separated from the upper surface of the upper part 62 of the partition 6. A distance Dx along the first direction X of a part of such sealing layers SE1, SE2, and SE3 has an equal distance at any portion around the sub-pixels SP1, SP2, and SP3. Note that although not shown here, a distance Dy along the second direction Y of a part of such sealing layers SE1, SE2, and SE3 likewise has an equal distance at any portion around the sub-pixels SP1, SP2, and SP3.

In the example of FIG. 3, the sealing layer SE1 on the partition 6 between the sub-pixels SP1 and SP2 is separated from the sealing layer SE2 on the partition 6. Also, the sealing layer SE1 on the partition 6 between the sub-pixels SP1 and SP3 is separated from the sealing layer SE3 on the partition 6.

The sealing layers SE1, SE2, and SE3 are covered by a resin layer 13. The resin layer 13 is also filled (arranged) on the upper surface of the upper part 62 of the partition 6 between the sub-pixels SP1 and SP2 and between the sealing layers SE1 and SE2. The resin layer 13 is also filled (arranged) on the upper surface of the upper part 62 of the partition 6 between the sub-pixels SP1 and SP3 and between the sealing layers SE1 and SE3. The resin layer 13 is covered by a sealing layer 14. The sealing layer 14 is covered by a resin layer 15. The resin layers 13 and 15 and the sealing layer 14 are continuously provided at least over the entire display area DA, and some of them extend to the peripheral area SA.

Cover members such as polarizing plates, touch panels, protective films, or cover glasses may be further arranged above the resin layer 15. Such cover members may be adhered to the resin layer 15 via an adhesive layer, such as an optical clear adhesive (OCA).

The organic insulating layer 12 is formed of an organic insulating material. The rib 5 and the sealing layers 14, SE1, SE2, and SE3 are formed of an inorganic insulating material such as silicon nitride (SiNx), silicon oxide (Siox), silicon oxynitride (SiON), or aluminum oxide (Al₂O₃). In one example, the rib 5 is formed of silicon oxynitride, and the sealing layers 14, SE1, SE2, and SE3 are formed of silicon nitride. The resin layers 13 and 15 are formed of a resin material (organic insulating material) such as epoxy resin or acrylic resin.

The lower electrodes LE1, LE2, and LE3 have a reflective layer formed of silver (Ag), for example, and a pair of conductive oxide layers covering the upper and lower surfaces of the reflective layer, respectively. Each conductive oxide layer can be formed of a transparent conductive oxide, such as indium tin oxide (ITO), indium zinc oxide (IZO), or indium gallium zinc oxide (IGZO).

The upper electrodes UE1, UE2, and UE3 are formed of a metallic material, such as an alloy of magnesium and silver (MgAg). For example, the lower electrodes LE1, LE2, and LE3 correspond to anodes, and the upper electrodes UE1, UE2, and UE3 correspond to cathodes.

The organic layers OR1, OR2, and OR3, for example, have a stacked structure of a hole injection layer, a hole transport layer, an electron blocking layer, a light-emitting layer, a hole blocking layer, an electron transport layer, and an electron injection layer. The organic layers OR1, OR2, and OR3 may have a so-called tandem structure including multiple light-emitting layers.

The cap layers CP1, CP2, and CP3, for example, have a stacked structure of a plurality of transparent thin films. The plurality of thin films may include thin films formed by inorganic materials and thin films formed by organic materials. The plurality of thin films have different refractive indices. The materials of these thin films are different from the materials of the upper electrodes UE1, UE2, and UE3 and are also different from the materials of the sealing layers SE1, SE2, and SE3. Note that at least one of the cap layers CP1, CP2, and CP3 may be omitted.

The lower part 61 of the partition 6 is formed, for example, by aluminum. The lower part 61 may be formed of an aluminum alloy such as aluminum-neodymium alloy (AlNd), aluminum-yttrium alloy (AlY), and aluminum-silicon alloy (AlSi), or may have a stacked structure of an aluminum layer and an aluminum alloy layer. Furthermore, the lower part 61 may have a bottom layer formed of a metallic material different from aluminum or aluminum alloy under the aluminum or aluminum alloy layer. As the metallic material forming such a bottom layer, molybdenum (Mo), titanium nitride (TiN), molybdenum-tungsten alloy (MoW), or molybdenum-niobium alloy (MoNb) can be used, for example.

For example, the upper part 62 of the partition 6 has a stacked structure with a lower layer formed of a metallic material and an upper layer formed of a conductive oxide. For example, titanium, titanium nitride, molybdenum, tungsten, molybdenum-tungsten alloy, or molybdenum-niobium alloy can be used as the metallic material forming the lower layer. For example, ITO or IZO can be used as the conductive oxide forming the upper layer. Note that the upper part 62 may have a monolayer structure of metallic material.

A common voltage is supplied to the partition 6. This common voltage is supplied to the upper electrodes UE1, UE2, and UE3, which are in contact with the side surfaces of the lower part 61, respectively. The lower electrodes LE1, LE2, and LE3 are supplied with a pixel voltage through the pixel circuit 1 that the sub-pixels SP1, SP2, and SP3 have respectively.

The organic layers OR1, OR2, and OR3 emit light in response to the application of voltage. Specifically, when a potential difference is formed between the lower electrode LE1 and the upper electrode UE1, the light-emitting layer of the organic layer OR1 emits light in a blue wavelength range. When a potential difference is formed between the lower electrode LE2 and the upper electrode UE2, the light-emitting layer of the organic layer OR2 emits light in a green wavelength range. When a potential difference is formed between the lower electrode LE3 and the upper electrode UE3, the light-emitting layer of the organic layer OR3 emits light in a red wavelength range.

As another example, the light-emitting layers of the organic layers OR1, OR2, and OR3 may emit light of the same color (e.g., white). In this case, the display device DSP may be provided with a color filter that converts the light emitted by the light-emitting layers into light of a color corresponding to the sub-pixels SP1, SP2, and SP3. The display device DSP may also be provided with a layer containing quantum dots that are excited by the light emitted by the light-emitting layer to generate light of a color corresponding to the sub-pixels SP1, SP2, and SP3.

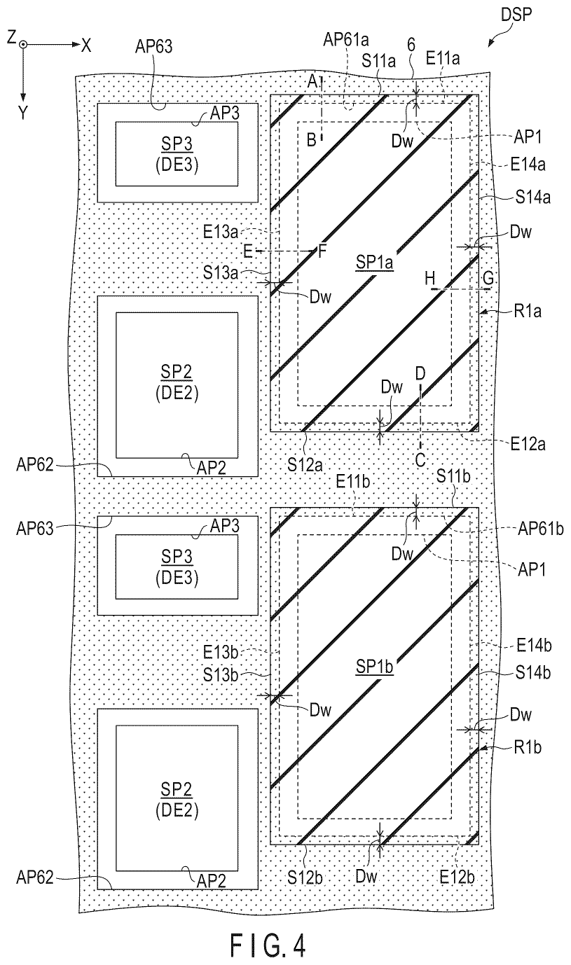

FIG. 4 is a schematic plan view of the display device DSP in a state where a resist R1 is arranged in a step of forming the display element DE1 in a manufacturing method according to the present embodiment.

The resist R1 is formed for patterning the stacked film FL1 and the sealing layer SE1 in the step of forming the display element DE1. The resist R1 is formed individually for each of the sub-pixels SP1 aligned in the second direction Y. In the example of FIG. 4, a resist R1a is formed for a sub-pixel SP1a in an upper part of the drawing and a resist R1b is formed for a sub-pixel SP1b in a lower part of the drawing. As described above, the resist R1 is formed individually for each of the sub-pixels SP1 aligned in the second direction Y. Therefore, the resists R1a and R1b are separated from each other as shown in FIG. 4.

The shape of the resists R1a and R1b in plan view is rectangular. The periphery of the resist R1a has a first side S11a, a second side S12a, a third side S13a, and a fourth side S14a. Similarly, the periphery of the resist Rib has a first side S11b, a second side S12b, a third side S13b, and a fourth side S14b.

The first side S11a of the resist R1a extends in the first direction X. The second side S12a of the resist R1a is located opposite the first side S11a in the second direction Y and extends in the first direction X. The third side S13a of the resist R1a extends in the second direction Y. The fourth side S14a of the resist R1a is located opposite the third side S13a in the first direction X and extends in the second direction Y.

Similarly, the first side S11b of the resist R1b extends in the first direction X. The second side S12b of the resist Rib is located opposite the first side S11b in the second direction Y and extends in the first direction X. The third side S13b of the resist R1b extends in the second direction Y. The fourth side S14b of the resist Rib is located opposite the third side S13b in the first direction X and extends in the second direction Y.

The resist R1a is larger than an aperture AP61a of the partition 6 surrounding the sub-pixel SP1a, and the periphery of the resist R1a overlaps with the partition 6 in plan view. Similarly, the resist R1b is larger than an aperture AP61b of the partition 6 surrounding the sub-pixel SP1b, and the periphery of the resist R1b overlaps with the partition 6 in plan view.

The shape of the apertures AP61a and AP61b in plan view is rectangular. The aperture AP61a has a first end portion Ella, a second end portion E12a, a third end portion E13a, and a fourth end portion E14a. The aperture AP61b has a first end portion El1b, a second end portion E12b, a third end portion E13b, and a fourth end portion E14b.

The first end portion Ella of the aperture AP61a extends in the first direction X. The second end portion E12a of the aperture AP61a is located opposite the first end portion Ella in the second direction Y and extends in the first direction X. The third end portion E13a of the aperture AP61a extends in the second direction Y. The fourth end portion E14a of the aperture AP61a is located opposite the third end portion E13a in the first direction X and extends in the second direction Y.

Similarly, the first end portion E11b of the aperture AP61b extends in the first direction X. The second end portion E12b of the aperture AP61b is located opposite the first end portion E11b in the second direction Y and extends in the first direction X. The third end portion E13b of the aperture AP61b extends in the second direction Y. The fourth end portion E14b of the aperture AP61b is located opposite the third end portion E13b in the first direction X and extends in the second direction Y.

The resist R1a is formed so that an overlap width in plan view with the partition 6 surrounding the sub-pixel SP1a is equal to each other on all four sides (in other words, the resist R1a is formed so that the overlap width in plan view with the partition 6 surrounding the sub-pixel SP1a is equal at any portion). Specifically, the resist R1a is formed such that a distance along the second direction Y from the first side S11a of the resist R1a to the first end portion Ella of the aperture AP61a, a distance along the second direction Y from the second side S12a of the resist R1a to the second end portion E12a of the aperture AP61a, a distance along the first direction X from the third side S13a of the resist R1a to the third end portion E13a of the aperture AP61a, and a distance along the first direction X from the fourth side S14a of the resist R1a to the fourth end portion E14a of the aperture AP61a are formed to have distances Dw that are equal to each other.

Similarly, the resist R1b is formed so that an overlap width in plan view with the partition 6 surrounding the sub-pixel SP1b is equal to each other on all four sides (in other words, the resist R1b is formed so that the overlap width in plan view with the partition 6 surrounding the sub-pixel SP1b is equal at any portion). Specifically, the resist Rib is formed such that a distance along the second direction Y from the first side S11b of the resist Rib to the first end portion E11b of the aperture AP61b, a distance along the second direction Y from the second side S12b of the resist R1b to the second end portion E12b of the aperture AP61b, a distance along the first direction X from the third side S13b of the resist Rib to the third end portion E13b of the aperture AP61b, and a distance along the first direction X from the fourth side S14b of the resist Rib to the fourth end portion E14b of the aperture AP61b are formed to have distances Dw that are equal to each other.

Details will be described later, but the distance Dw is set to a value that enables removal of all of the stacked film FL1 on the partition 6 by side etching when etching is performed using the resists R1a and R1b as masks.

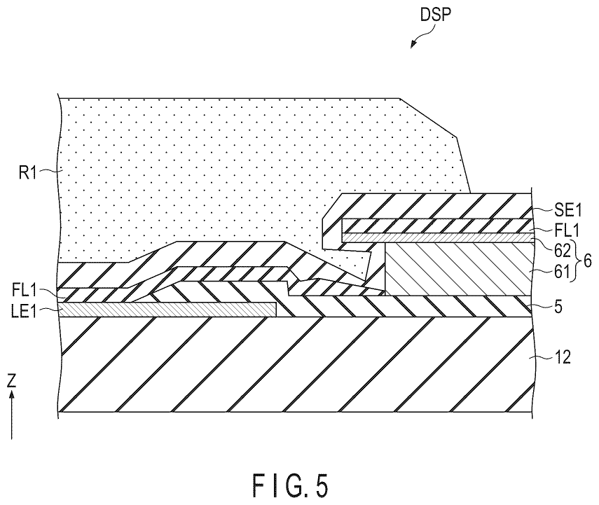

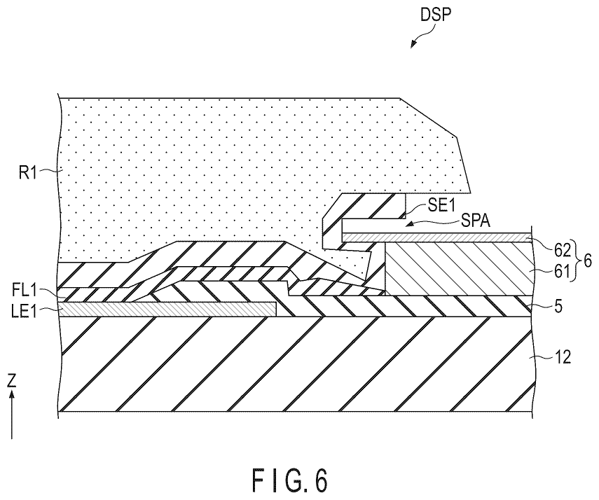

FIG. 5 and FIG. 6 are cross-sectional views for illustrating the manufacturing method according to the present embodiment and steps of forming the display element DE1.

In forming the display element DE1, the stacked film FL1 and the sealing layer SE1 are formed on the entire substrate 10 as shown in FIG. 5. The stacked film FL1 includes the organic layer OR1 contacting the lower electrode LE1 through the pixel aperture AP1, the upper electrode UE1 covering the organic layer OR1, and the cap layer CP1 covering the upper electrode UE1, as shown in FIG. 3. The organic layer OR1, the upper electrode UE1, and the cap layer CP1 are formed by vapor deposition. The sealing layer SE1 is formed by chemical vapor deposition (CVD).

The stacked film FL1 is divided by the overhanging partition 6 into a portion covering the lower electrode LE1 and the rib 5 (first portion) and a portion on the partition 6 (second portion). The sealing layer SE1 continuously covers each of the divided portions of the stacked film FL1 and the partition 6.

As shown in FIG. 5, the resist R1 is formed on the sealing layer SE1 in a manner covering the sub-pixel SP1. The resist R1 is formed so that the overlap width in plan view with the partition 6 becomes the distance Dw, as shown in FIG. 4.

Thereafter, by etching using the resist R1 as a mask, a portion exposed from the resist R1 is removed from the stacked film FL1 and the sealing layer SE1 as shown in FIG. 6, and the display element DE1 is formed in the sub-pixel SP1. In the vicinity of the periphery of the resist R1, side etching removes elements in the vicinity of the periphery of the resist R1, specifically, a part of the sealing layer SE1 covering the stacked film FL1 on the partition 6 and the stacked film FL1 on the partition 6. According to this, a gap SPA is formed between the sealing layer SE1 covering the stacked film FL1 on the partition 6 and the upper surface of the upper part 62 of the partition 6, as shown in FIG. 6. Such a gap SPA is formed to surround the sub-pixel SP1 in plan view.

Note that the cross section shown in FIG. 6 corresponds, for example, to the cross sections of the display device DSP along line A-B, line C-D, line E-F, and line G-H of FIG. 4. In the manufacturing method according to the present embodiment, since the resist R1 is formed so that the overlap width in plan view with the partition 6 is the distance Dw in all cases, all of the stacked film FL1 on the partition 6 is removed (or uniformly removed) in all cross sections.

Although a detailed description is omitted here, in a step of forming the display element DE2 on the sub-pixel SP2, a rectangular resist is also arranged individually for each of the sub-pixels SP2, and the resist is formed so that the overlap width in plan view with the partition 6 surrounding the sub-pixel SP2 is equal on all four sides (e.g., to become the distance Dw). Therefore, all of the stacked film FL2 on the partition 6 is removed (or uniformly removed). Similarly, in a step of forming the display element DE3 on the sub-pixel SP3, a rectangular resist is also arranged individually for each of the sub-pixels SP3, and the resist is formed so that the overlap width in plan view with the partition 6 surrounding the sub-pixel SP3 is equal on all four sides (e.g., to become the distance Dw). Therefore, all of the stacked film FL3 on the partition 6 is removed (or uniformly removed). After the display elements DE1, DE2, and DE3 are formed, the resin layer 13, the sealing layer 14, and the resin layer 15 are formed to realize the structure of the display device DSP shown in FIG. 3.

Note that the portion exposed from the resist R1 includes that between the two sub-pixels SP1a and SP1b aligned in the second direction Y, as shown in FIG. 4. Therefore, the stacked film FL1 arranged on the partition 6 between the two sub-pixels SP1a and SP1b aligned in the second direction Y and the sealing layer SE1 covering the stacked film FL1 are removed by the etching described above, and the display device DSP according to the present embodiment has a structure in which the stacked film FL1 and the sealing layer SE1 are not arranged on the partition 6 between the two sub-pixels SP1a and SP1b.

In the following, the effects of the manufacturing method and the display device DSP according to the present embodiment will be explained using a comparative example. Note that the comparative example is intended to illustrate some of the effects that the manufacturing method and the display device DSP according to the present embodiment can achieve, and does not exclude from the scope of the present invention the effects common to the present embodiment and the comparative example.

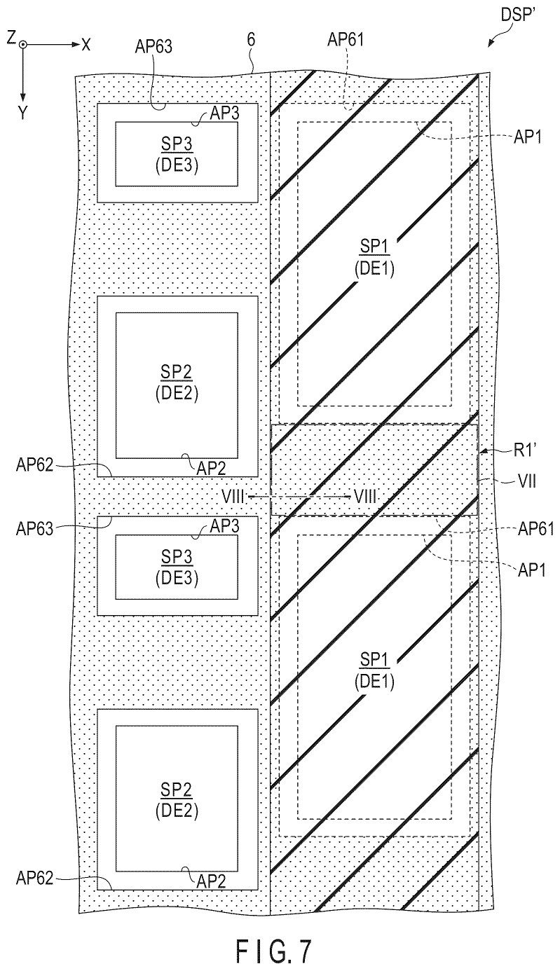

FIG. 7 illustrates a step of forming a display device DE1 in a manufacturing method according to the comparative example, and is a schematic plan view of a display device DSP′ with a resist R1′ arranged. The manufacturing method according to the comparative example differs from the manufacturing method according to the present embodiment in that, as shown in FIG. 7, one resist R1′ is arranged for a plurality of sub-pixels SP1 lined up in a second direction Y in the step of forming the display element DE1.

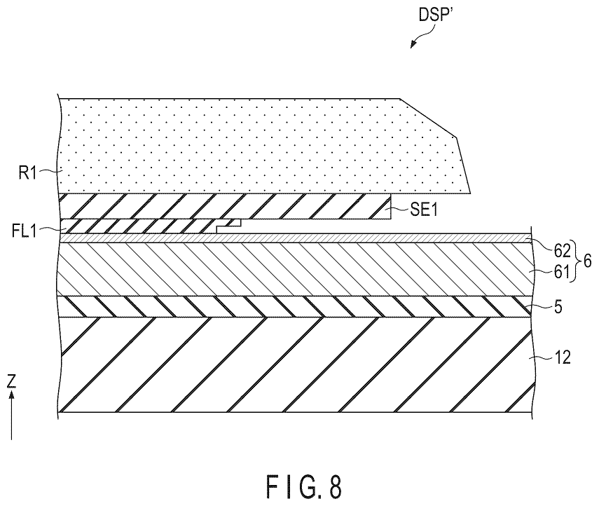

FIG. 8 is a schematic cross-sectional view of the display device DSP′ along line VIII-VIII of FIG. 7. For example, in an area VII surrounded by a dashed line in FIG. 7, the entire surface of the resist R1′ overlaps the partition 6 in plan view. Therefore, when etching is performed using the resist R1′ as a mask, side etching cannot completely remove the stacked film FL1 on the partition 6, and as shown in FIG. 8, the stacked film FL1 on the partition 6 remains as residue at a position far from the periphery of the resist R1′. Such residue causes display irregularities and reduce the reliability of the display device.

In contrast, in the manufacturing method according to the present embodiment, in the step of forming the display element DE1, the resist R1 is individually arranged for each of the sub-pixels SP1 aligned in the second direction Y, and the resist R1 is formed so that the overlap width in plan view with the partition 6 surrounding the sub-pixel SP1 is equal on all four sides (e.g., to become the distance Dw). Therefore, it is possible to remove (uniformly remove) all of the stacked film FL1 on the partition 6. According to this, since the stacked film FL1 on the partition 6 does not remain as residue, it is possible to suppress the occurrence of the display irregularities described above. That is, the degradation of the reliability of the display device can be suppressed.

According to one embodiment described above, it is possible to provide a method for manufacturing a display device and a display device capable of suppressing degradation of reliability.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A manufacturing method for a display device comprising a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction, the manufacturing method comprising:
forming a plurality of lower electrodes, including a first lower electrode configuring the first sub-pixel, in the display area;
forming a rib having a plurality of pixel apertures including a first pixel aperture overlapping the first lower electrode;
forming a partition, including a lower part arranged on the rib and an upper part having an end portion protruding from a side surface of the lower part, in the display area;
forming a first stacked film including a first organic layer in contact with the plurality of lower electrodes through the plurality of pixel apertures and a first upper electrode covering the first organic layer;
forming a first sealing layer covering the first stacked film;
forming a resist individually for each of a plurality of first sub-pixels aligned in the second direction; and
removing the first sealing layer and the first stacked film using the resists as a mask.

2. The manufacturing method for the display device of claim 1, wherein
the first stacked film is divided by the partition into a first portion covering the rib and the plurality of lower electrodes and a second portion on the partition,
the first sealing layer continuously covers the first portion and the second portion, and
the removing the first sealing layer and the first stacked film includes removal of the first sealing layer and the first stacked film exposed from the resists, a part of the first sealing layer covering the second portion, and the second portion.

3. The manufacturing method for the display device of claim 2, wherein the removing the first sealing layer and the first stacked film includes formation of a gap between the first sealing layer covering the second portion and an upper surface of the upper part included in the partition.

4. The manufacturing method for the display device of claim 1, wherein
the partition is formed to have an aperture in the first sub-pixel, the second sub-pixel, and the third sub-pixel, respectively, and
each of the resists is formed so that it is larger than the aperture in the first sub-pixel and a periphery of the resist overlaps the partition in plan view.

5. The manufacturing method for the display device of claim 4, wherein each of the resists is formed so that an overlap width in plan view with the partition surrounding the first sub-pixel is equal at any portion.

6. A display device comprising a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction, the display device comprising:
a lower electrode arranged in the display area;
a rib having a pixel aperture overlapping the lower electrode;
a partition including a lower part arranged on the rib and an upper part having an end portion protruding from a side surface of the lower part;
a stacked film including an organic layer in contact with the lower electrode through the pixel aperture and an upper electrode covering the organic layer; and
a sealing layer covering the stacked film, wherein
a part of the sealing layer overlaps in plan view with the upper part included in the partition, and
a gap is formed between a part of the sealing layer and an upper surface of the upper part included in the partition.

7. The display device of claim 6, further comprising a resin layer covering the sealing layer, wherein the resin layer is arranged in the gap.

8. The display device of claim 6, wherein the stacked film and the sealing layer are not arranged on a partition between two first sub-pixels aligned in the second direction.

9. The display device of claim 6, wherein a distance along the first direction and a distance along the second direction of a part of the sealing layer are equal at any portion around the first sub-pixel, the second sub-pixel, and the third sub-pixel.

10. A display device comprising a display area including pixels which are arranged in a matrix in a first direction and a second direction intersecting the first direction and include a first sub-pixel, a second sub-pixel and a third sub-pixel such that the second and third sub-pixels are aligned with the first sub-pixel in the first direction, respectively, and the second sub-pixel and the third sub-pixel are aligned in the second direction, the display device comprising:
a lower electrode configuring the first sub-pixel;
a rib having a pixel aperture overlapping the lower electrode;
a partition including a lower part arranged on the rib and an upper part having an end portion protruding from a side surface of the lower part; and
a sealing layer and a stacked film patterned using a resist formed individually for each of a plurality of first sub-pixels aligned in the second direction as a mask, wherein
the stacked film includes an organic layer in contact with the lower electrode through the pixel aperture and an upper electrode covering the organic layer.
